(19) United States
(12) Patent Application Publication
(10) Pub. No.: US 2010/0283768 A1
(43) Pub. Date: Nov. 11, 2010

(54) Output Buffer Adapted to a Source Driver and Source Driver

(75) Inventors: Meng-Tse Weng, Sinshih Township (TW); Chien-Ru Chen, Sinshih Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX TECHNOLOGIES LIMITED, Sinshih Township (TW)

(21) Appl. No.: 12/437,694

(22) Filed: May 8, 2009

(51) Int. Cl. G06F 3/038; H03K 3/00

(52) U.S. Cl. 345/204; 327/108; 345/98

(57) ABSTRACT

An output buffer adapted to a source driver and a source driver are provided. The output buffer comprises an input and an output stage. The input stage comprises an input node, a first and a second output terminal. The output stage comprises a PMOS, a NMOS, a first and a second switches. The first and the second switch are connected between the gate of the PMOS, the first output terminal and the gate of the PMOS, the voltage supply respectively to both receive a latch signal. When the latch signal is in a first state, the first and the second switches disable the output stage. When the latch signal is in a second state, the first and the second switches enable the output stage to transfer an analog data from a DAC of the source driver to the output node connected to the drain of the PMOS and NMOS.

### BACKGROUND

1. Field of Invention

The present invention relates to an output buffer adapted to a source driver. More particularly, the present invention relates to an output buffer adapted to a source driver and a source driver adapted to a liquid crystal display.

2. Description of Related Art

Liquid crystal display (LCD) devices generally are smaller, thinner, and require less power than the other types of conventional display devices. Accordingly, LCD devices are applied to electronic apparatuses such as notebook computers and mobile phones, for example. The source driver of the liquid crystal display is to transfer the digital data into the analog data and send the analog data to the pixel array through the output buffer in the source driver during a driving period and stop to send the analog data during non-driving period. However, during the non-driving period, the output of the output buffer is in a Hi-Z state. A short current condition will occur during the Hi-Z state to make the temperature of the circuit raise, which is an undesirable result.

Accordingly, what is needed is an output buffer adapted to a source driver and a source driver adapted to a liquid crystal display that prevents the generation of the short current. The present invention addresses such a need.

### SUMMARY

An output buffer adapted to a source driver is provided. The output buffer comprises an input stage and an output stage. The input stage comprises an input node, a first output terminal and a second output terminal, wherein the input node receives an analog data from a digital-to-analog converters (DAC) of the source driver; and the output stage comprises a PMOS, a NMOS a first and a second switches. The PMOS comprises a gate, a source connected to a first voltage supply and a drain connected to an output node. The NMOS comprises a gate, a source connected to a second voltage supply and a drain connected to the output node. The first switch is connected between the gate of the PMOS and the first output terminal and the second switch is connected between the gate of the PMOS and the voltage supply, wherein the first and the second switches receive a latch signal such that when the latch signal is in a first state, the first switch turns off and the second switch turn on to make the gate of the PMOS receive the first power supply to disable the output stage to prevent a short current condition and when the latch signal is in a second state, the first switch turns on and the second switch turns off to enable the output stage to transfer the analog data to the output node.

Another object of the present invention is to provide a source driver adapted in a liquid crystal display. The source driver comprises a plurality of registers, a plurality of DACs and a plurality of output buffers. The plurality of registers are to receive a digital data. Each of the plurality of DACs is connected to a register to convert a digital data from a register into an analog signal. The plurality of output buffers each connected to a DAC, wherein each of the output buffers comprises: an input stage and an output stage. The input stage comprises an input node, a first output terminal and a second output terminal, wherein the input node receives an analog data from a digital-to-analog converters (DAC) of the source driver; and the output stage comprises a PMOS, a NMOS a first and a second switches. The PMOS comprises a gate, a source connected to a first voltage supply and a drain connected to an output node. The NMOS comprises a gate, a source connected to a second voltage supply and a drain connected to the output node. The first switch is connected between the gate of the PMOS and the first output terminal and the second switch is connected between the gate of the PMOS and the voltage supply, wherein the first and the second switches receive a latch signal such that when the latch signal is in a first state, the first switch turns off and the second switch turn on to make the gate of the PMOS receive the first power supply to disable the output stage to prevent a short current condition and when the latch signal is in a second state, the first switch turns on and the second switch turns off to enable the output stage to transfer the analog data to the output node.

The advantage of the present invention is to control the activity of the output buffer through the first and the second switches to prevent the short current condition.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a diagram of a liquid crystal display of an embodiment of the present invention;

FIG. 2 is a more detailed diagram of the liquid crystal display of an embodiment of the present invention;

FIG. 3 is a diagram of the output buffer of an embodiment of the present invention;

FIG. 4 is a timing diagram of the latch signal, the analog signal, the waveform of the signal on the data line and the signal on the scan line within a data-transferring period;

FIG. 5A is another diagram of the output buffer during the first state of an embodiment of the present invention;

FIG. 5B is the diagram of the output buffer during the second state of an embodiment of the present invention;

FIG. 6 is the diagram of the output buffer in another embodiment of the present invention;

FIG. 7A is another diagram of the output buffer during the first state of an embodiment of the present invention; and

FIG. 7B is the diagram of the output buffer during the second state of an embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

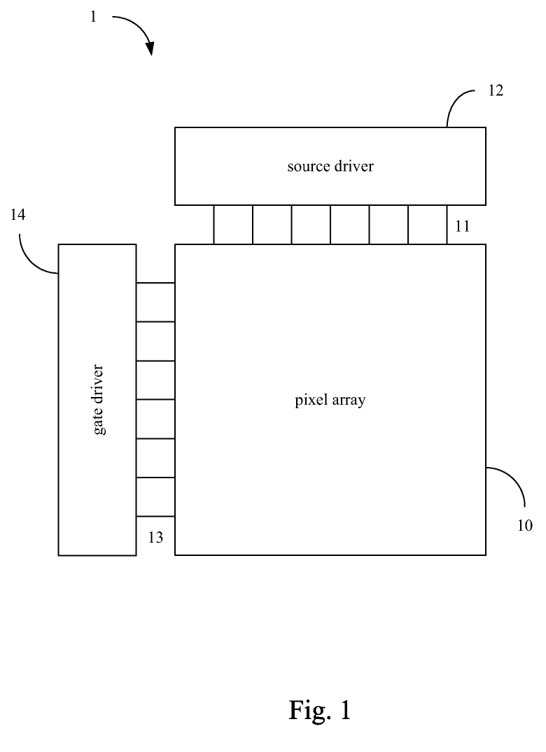

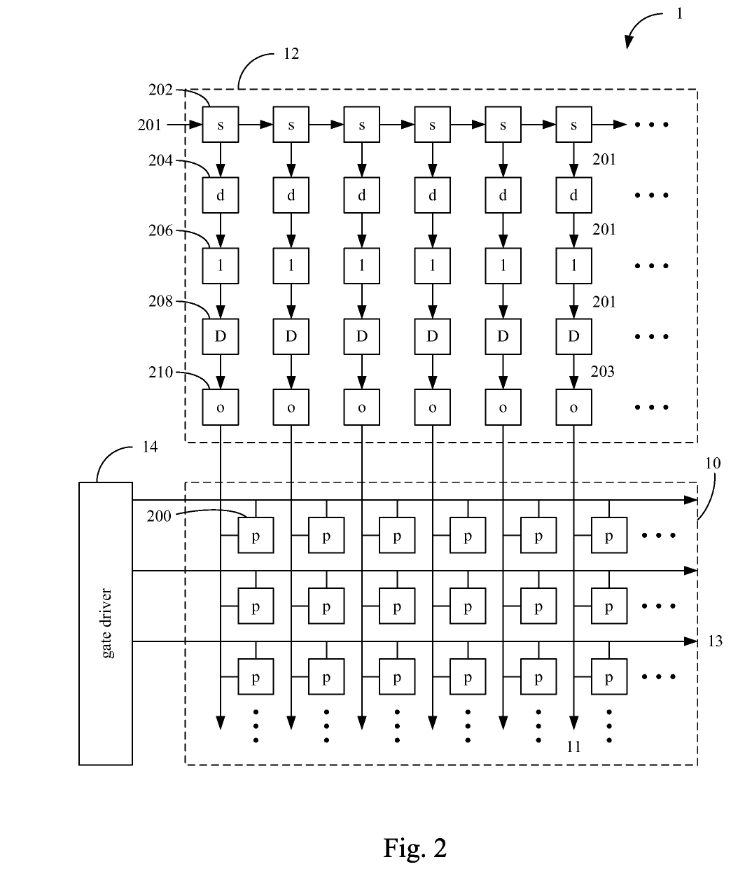

Please refer to FIG. 1. FIG. 1 is a diagram of a liquid crystal display 1 of an embodiment of the present invention. The liquid crystal display 1 comprises a pixel array 10, a source driver 12 and a gate driver 14. The source driver 12 is connected to the pixel array 10 through a plurality of data lines 11 and the gate driver 14 is connected to the pixel array 10 through a plurality of scan lines 13. Each of the scan lines 13 of the gate driver 14 is to activate the pixels on a row of the pixel array 10 in a sequential order. Please refer to FIG. 2 at the same time. FIG. 2 is a more detailed diagram of the liquid crystal display 1. The pixel array 10 comprises a plurality of pixels 200. The source driver 12 comprises a plurality of shift registers 202, a plurality of data registers 204, a plurality of level shifters 206, a plurality of DACs 208 and a plurality of output buffers 210. The plurality of shift registers 202 are connected in a serial manner to substantially receive the digital data 201. Each of the plurality of data registers 204 is connected to a shift register 202 to receive the digital data 201. Each of the plurality of level shifters 206 is connected to a data register 204 to perform a level-shifting process on the digital data 201 from the data registers 204. Each of the plurality of DACs 208 is connected to a level shifter 206 to convert the digital data 201 from the level shifters 206 into an analog signal 203. Each of the plurality of output buffers 210 is connected to a DAC 208. And the other end of each of the plurality of output buffers 210 is further connected to a data line 11. Each scan line 13 is connected between the gate driver 14 and a row of pixels 200.

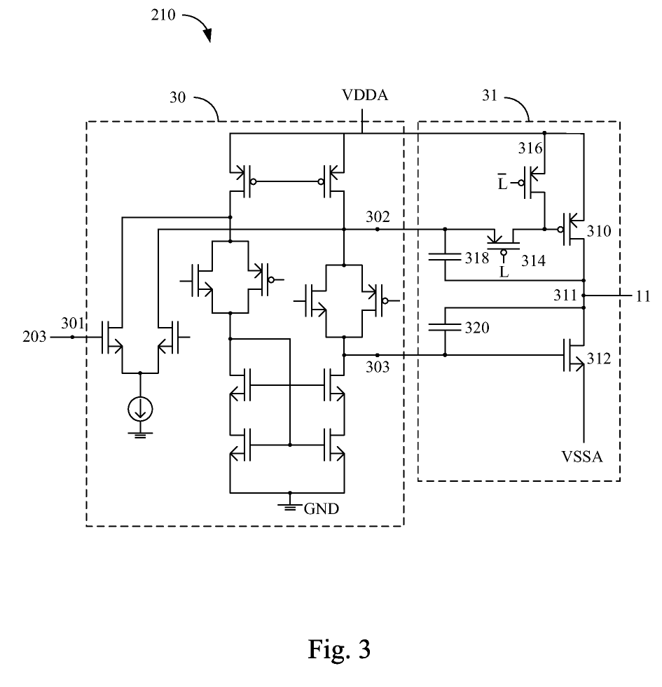

FIG. 3 is a diagram of the output buffer 210 of an embodiment of the present invention. The output buffer 210 comprises an input stage 30 and an output stage 31. The input stage 30 comprises an input node 301, a first output terminal 302 and a second output terminal 303, wherein the input node 301 receives the analog data 203 from the DAC 208 as depicted in FIG. 2. The output stage 31 comprises a PMOS 310, a NMOS 312, a first switch 314 and a second switch 316. The PMOS 310 comprises a gate, a source connected to a first voltage supply VDDA and a drain connected to an output node 311. The NMOS 312 comprises a gate, a source connected to a second voltage supply VSSA and a drain connected to the output node 311. The first switch 314 is connected between the gate of the PMOS 310 and the first output terminal 302 and the second switch 316 is connected between the gate of the PMOS 310 and the first voltage supply VDDA. The first and the second switches 314 and 316 of the output buffer 210 are to receive a latch signal respectively, wherein the first switch 314 receives the latch signal L. and the second switch 316 receives the latch signal L. Each of the shift register 202 in FIG. 2 substantially receives a latch signal L (not shown in FIG. 2) as well. In the embodiment, the first switch 314 and the second switch 316 are PMOS transistors. It's noticed that a capacitor 318 is connected between the first output terminal 302 and the output node 311 and a capacitor 320 is connected between the second output terminal 303 and the output node 311. Both of the capacitor 318 and the capacitor 320 are miller capacitors.

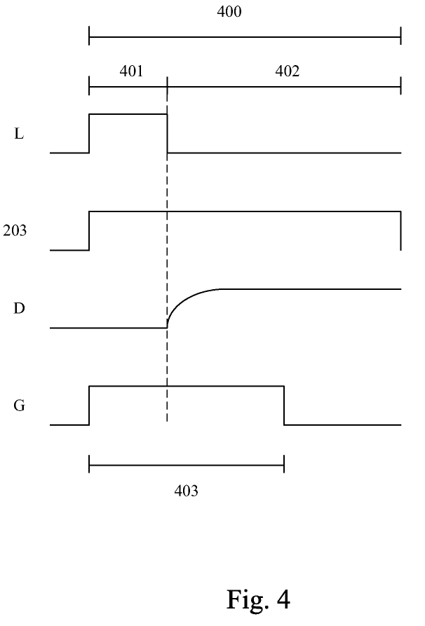

Please refer to FIG. 2, FIG. 3 and FIG. 4 at the same time, wherein FIG. 4 is a timing diagram of the latch signal L, the analog signal 203, the waveform of the signal D on the data line 11 and the signal G on the scan line 13 within a data-transferring period 400. The latch signal L has a first state 401 and a second state 402. When the latch signal L is in the first state 401, which is a high state in the present embodiment, each of the shift register 202 receives the digital data 201 and immediately transfers the digital data 201 to the corresponding data register 204. The data line 11 is substantially controlled by the latch signal L as well. Thus, the output node 311 is in a high-Z state to stop transferring the analog signal 203 from the output buffer 210 to the data line 11 during the first state 401 of the latch signal L, making the signal D on the data line 11 a low state. However, the first and the second switches 314 and 316 of the output buffer 210 and the data registers 204 receive the latch signal L as well such that when the latch signal L is in the first state 401, each of the data register 204 holds the digital data 201, the first switch 314 turns off and the second switch 316 turns on to make the gate of the PMOS 310 receive the first power supply VDDA to disable the output stage 31 (PMOS 310 turns off) to prevent a short current condition. When the latch signal L is in the second state 402, the data register 204 transfers the digital data 201 through the level shifter 206 and the DAC 208 to become the analog signal 203, the first switch 314 turns on and the second switches 316 turns off to enable the output stage 31 to transfer the analog data 203 to the output node 311. The scan line 13 activates a row of pixels 200 during an activation period 403 when the signal G of the scan line 13 is high. The overlap of the activation period 403 and the first state 401 of the latch signal L is the initial period to initialize the transferring of the data. The overlap of the activation period 403 and the second state 402 of the latch signal L is the driving period to actually transfer the analog data 203. Thus, during the driving period, the scan line 13 activates the corresponding row of pixels 200, the row of pixels 200 receive the analog data 203 from the output node 311 of the output buffer 210 through the corresponding data line 11.

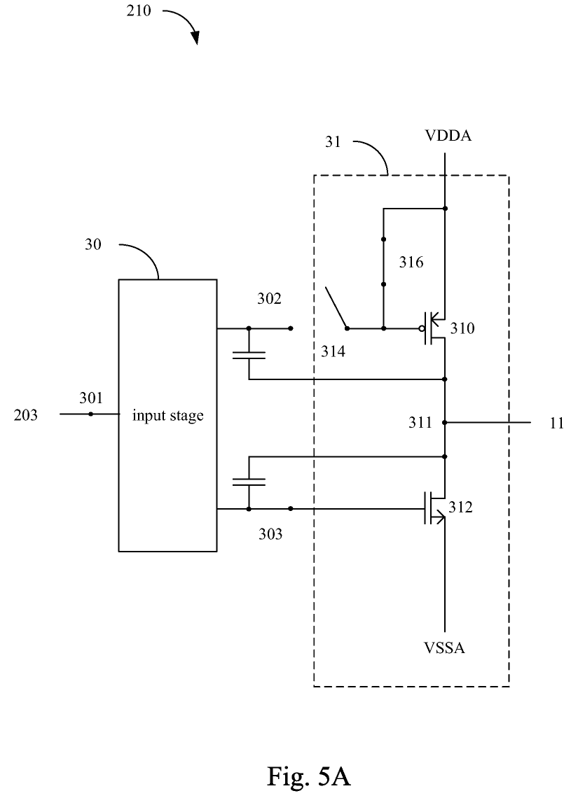

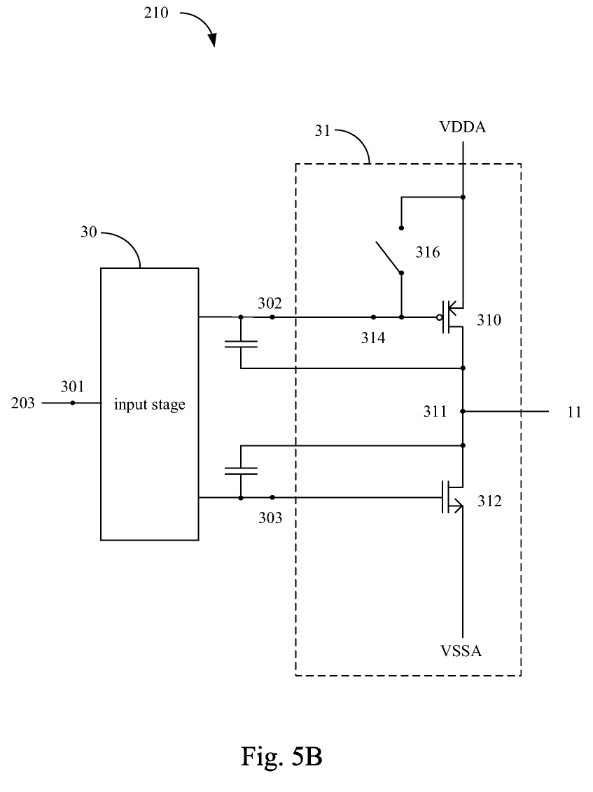

Please refer to FIG. 4 and FIG. 5A at the same time. FIG. 5A is another diagram of the output buffer 210 during the first state 401 of an embodiment of the present invention. The latch signal L is high during the first state 401 to make the first switch 314 turn off and the second switch 316 turn on. The turn-off of the first switch 314 disconnects the input stage 30 and the output stage 31. The turn-on of the second switch 316 makes the gate of the PMOS 310 receive the first power supply VDDA to completely stop the operation of the PMOS 310. Thus, the first and the second switch 314 and 316 disable the output stage 31. Please refer to FIG. 4 and FIG. 5B at the same time. FIG. 5B is the diagram of the output buffer 210 during the second state 402 of an embodiment of the present invention. The latch signal L is low during the second state 402 to make the first switch 314 turn on and the second switch 316 turn off. The turn-on of the first switch 314 connects the input stage 30 and the output stage 31. The turn-off of the second switch 316 makes the gate of the PMOS 310 and the first power supply VDDA disconnected to start the operation of the PMOS 310. Thus, the first and the second switch 314 and 316 enable the output stage 31.

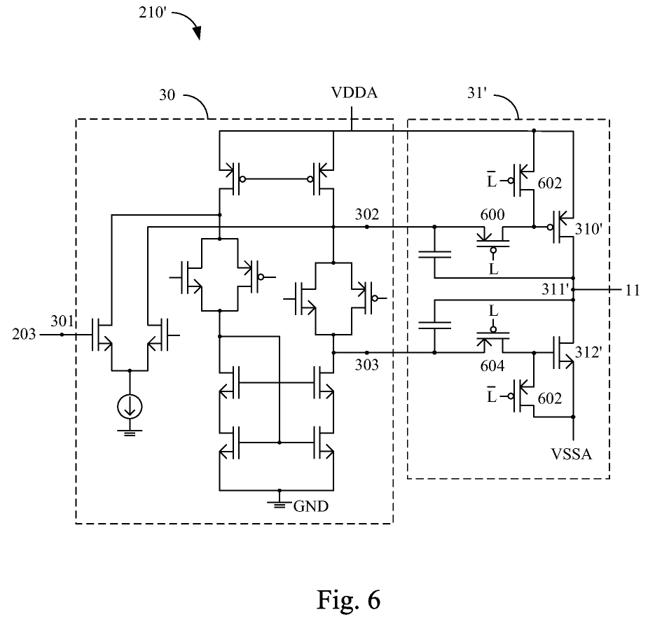

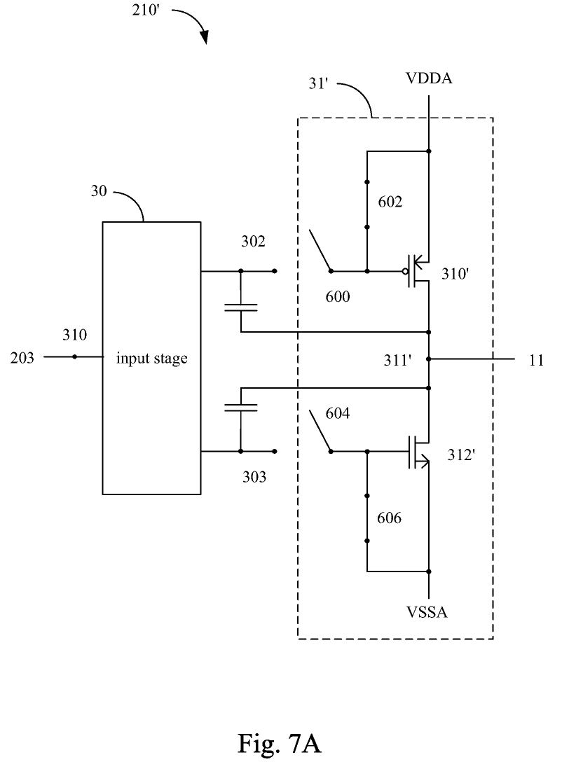

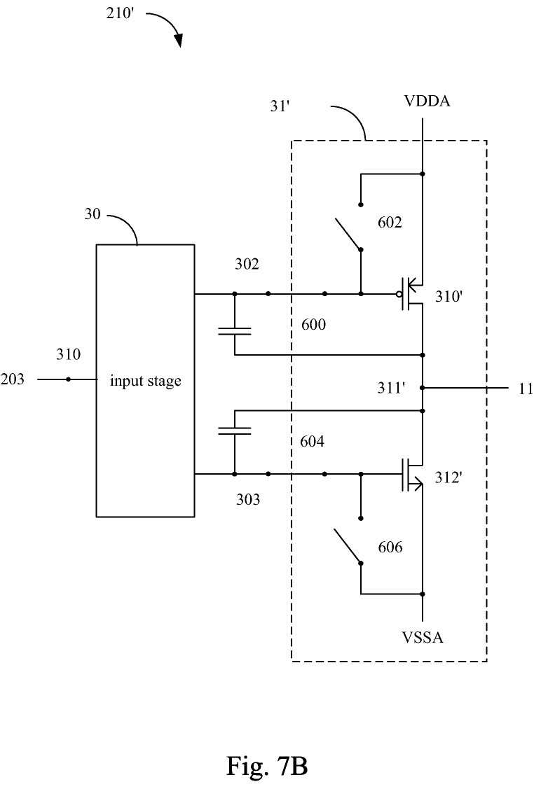

Please refer to FIG. 6. FIG. 6 is the diagram of the output buffer 210′ in another embodiment of the present invention. The input stage 30 of the output buffer 210′ of the present embodiment is the same as the former embodiment. The output stage 31′ of the present embodiment comprises a PMOS 310′, a NMOS 312′, a first switch 600, a second switch 602, a third switch 604 and a fourth switch 606. The PMOS 310′ comprises a gate, a source connected to a first voltage supply VDDA and a drain connected to an output node 311′. The NMOS 312′ comprises a gate, a source connected to a second voltage supply VSSA and a drain connected to the output node 311′. The first switch 600 is connected between the gate of the PMOS 310′ and the first output terminal 302, the second switch 602 is connected between the gate of the PMOS 310′ and the first voltage supply VDDA, the third switch 604 is connected between the gate of the NMOS 312′ and the second output terminal 303 and the fourth switch 606 is connected between the gate of the NMOS 312′ and the second voltage supply VSSA. The first, the second, the third and the fourth switches 600, 602, 604 and 606 of the output buffer 210′ are to receive the latch signal respectively, wherein the first and the third switches 600 and 604 receive the latch signal L and the second and the fourth switches 602 and 606 receive the latch signal L̅. Please refer to FIG. 4, FIG. 6 and FIG. 7A at the same time. FIG. 7A is another diagram of the output buffer 210′ during the first state 401 of an embodiment of the present invention. When the latch signal L is in the first state 401, the first switch 600 turns off, the second switch 602 turns on to make the gate of the PMOS 310′ receive the first power supply VDDA, the third switch 604 turns off and the fourth switch 606 turns on to make the gate of the NMOS 312′ connected to the second voltage supply VSSA to disable the output stage 31′ to prevent a short current condition. Please refer to FIG. 4, FIG. 6 and FIG. 7B at the same time. FIG. 7B is the diagram of the output buffer 210′ during the second state 402 of an embodiment of the present invention. When the latch signal L is in the second state 402, the first and the third switches 600 and 604 turn on to connect the input and the output stage 30 and 31′, the second and the fourth switches 602 and 606 turn off to enable the output stage 31′ to transfer the analog data 203 to the output node 311′.

The advantage of the present invention is to control the activity of the output buffer through the switches to prevent the short current condition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An output buffer adapted to a source driver comprising:
an input stage comprising an input node, a first output terminal and a second output terminal, wherein the input node receives an analog data from a digital-to-analog converters (DAC) of the source driver; and
an output stage comprising:
a PMOS comprising a gate, a source connected to a first voltage supply and a drain connected to an output node;
a NMOS comprising a gate, a source connected to a second voltage supply and a drain connected to the output node;
a first switch connected between the gate of the PMOS and the first output terminal; and
a second switch connected between the gate of the PMOS and the first voltage supply;
wherein the first and the second switches receive a latch signal such that when the latch signal is in a first state, the first switch turns off and the second switch turn on to make the gate of the PMOS receive the first power supply to disable the output stage to prevent a short current condition and when the latch signal is in a second state, the first switch turns on and the second switch turns off to enable the output stage to transfer the analog data to the output node.

2. The output buffer of claim 1, further comprising:
a third switch connected between the gate of the NMOS and the second output terminal; and
a fourth switch connected between the gate of the NMOS and the second voltage supply; wherein the third and the fourth switches receive the latch signal such that when the latch signal is in a first state, the third switch turns off and the fourth switch turns on to make the gate of the NMOS connected to the second voltage supply to disable the output stage to prevent the short current condition and when the latch signal is in a second state, the third switch turns on and the fourth switch turns off to enable the output stage to transfer the analog data to the output node.

3. The output buffer of claim 1, wherein the source driver is adapted to a liquid crystal display comprising a pixel array, a data line of the pixel array is connected to the output node to receive the analog data.

4. The output buffer of claim 3, when a scan line of the pixel array activates the corresponding row of pixels of the pixel array and the latch signal is in the second state, the row of pixels receive the analog data from the corresponding data line.

5. The output buffer of claim 4, wherein the scan line activates the pixels on the row of the pixel array in a sequential order.

6. The output buffer of claim 5, wherein the scan line activates each pixel during an activation period, wherein the activation period comprises an initial period and a driving period, the latch signal is in the first state during the initial period, and the latch signal is in the second state during the driving period.

7. The output buffer of claim 1, wherein the first voltage supply is higher than the second voltage supply.

8. A source driver adapted in a liquid crystal display comprising:
a plurality of registers to receive a digital data;
a plurality of DACs (digital-to-analog converter) each connected to a register to convert a digital data from a register into an analog signal; and
a plurality of output buffers each connected to a DAC, wherein each of the output buffer comprises:
an input stage comprising an input node, a first output terminal and a second output terminal, wherein the input node receives the analog data from the DAC;
an output stage comprising:
a PMOS comprising a gate, a source connected to a first voltage supply and a drain connected to an output node; and
a NMOS comprising a gate, a source connected to a second voltage supply and a drain connected to the output node;
a first switch connected between the gate of the PMOS and the first output terminal; and
a second switch connected between the gate of the PMOS and the voltage supply;
wherein the first and the second switches of each output buffer and each of the register receive a latch signal such that when the latch signal is in a first state, each of the register holds the digital data, the first switch turns off and the second switch turns on to make the gate of the PMOS receive the first power supply to disable the output stage to prevent a short current condition and when the latch signal is in a second state, each of the register transfer the digital data through the DAC to become the analog signal, the first turns on and the second switch turns off to enable the output stage to transfer the analog data to the output node.

9. The source driver of claim 8, wherein each of the output buffer further comprises:
a third switch connected between the gate of the NMOS and the second output terminal; and
a fourth switch connected between the gate of the NMOS and the second voltage supply; wherein the third and the fourth switches receive the latch signal such that when the latch signal is in a first state, the third switch turns off and the fourth switch turns on to make the gate of the NMOS connected to the second voltage supply to disable the output stage to prevent the short current condition and when the latch signal is in a second state, the third switch turns on and the fourth switch turns off to enable the output stage to transfer the analog data to the output node.

10. The source driver of claim 8, wherein the liquid crystal display comprises a pixel array, a data line of the pixel array is connected to the output node of an output buffer to receive the analog data.

11. The source driver of claim 10, when a scan line of the pixel array activates the corresponding row of pixels of the pixel array and the latch signal is in the second state, the row of pixels receive the analog data from the data line.

12. The source driver of claim 11, wherein the scan line activates the pixels on the row of the pixel array in a sequential order.

13. The source driver of claim 12, wherein scan line activates each pixel during an activation period, wherein the activation period comprises an initial period and a driving period, the latch signal is in the first state during the initial period, and the latch signal is in the second state during the driving period.

14. The source driver of claim 8, wherein the first voltage supply is higher than the second voltage supply.

15. The source driver of claim 8, wherein the plurality of registers comprise:
a plurality of shift registers to substantially receive the digital data; and
a plurality of data registers each connected to a shift register, when the latch signal is in the first state, each of the shift register receives the digital data and immediately transfers the digital data to the corresponding data register, wherein each of the DAC is substantially connected to a data register to convert the digital data from the data register into the analog signal.

16. The source driver of claim 15, further comprising a plurality of level shifter each connected between a data register and a DAC to perform a level-shifting process.
